(19) United States
(12) Patent Application Publication
(10) Pub. No.: US 2026/0268855 A1
(43) Pub. Date: Sep. 10, 2026

(54) DISPLAY DEVICE, METHOD OF DRIVING DISPLAY DEVICE, AND ELECTRONIC DEVICE INCLUDING THE DISPLAY DEVICE

(71) Applicant: SAMSUNG DISPLAY CO., LTD., YONGIN-SI (KR)

(72) Inventors: Jun Hyun PARK, YONGIN-SI (KR); Hwa-Rang LEE, YONGIN-SI (KR); Na Hyeon CHA, YONGIN-SI (KR)

(21) Appl. No.: 19/328,280

(22) Filed: Sep. 15, 2025

(30) Foreign Application Priority Data
Mar. 4, 2025 (KR) 10-2025-0027700

(51) Int. Cl. G09G 3/3266; G09G 3/3275

(52) U.S. Cl. CPC G09G 3/3266; G09G 3/3275; G09G 2300/043; G09G 2300/0814; G09G 2320/0233

(57) ABSTRACT

A display device includes: a display panel including a first pixel connected to a first row and including a first switching transistor and a first driving transistor; a gate driver connected to the display panel through a plurality of gate lines and including a logic unit for applying a first gate signal to the first pixel through a gate line corresponding to the first pixel among the plurality of gate lines; and a data driver connected to the display panel through a data line and applying a first data signal to the first pixel. The first gate signal may apply a third voltage level to the first switching transistor for a predetermined time period, where the third voltage level is an intermediate voltage level between a first voltage level for turning on the first switching transistor and a second voltage level for turning off the first switching transistor.

### CROSS-REFERENCE TO RELATED APPLICATION

This application claims priority to Korean Patent Application No. 10-2025-0027700 filed in the Korean Intellectual Property Office on Mar. 4, 2025, the entire disclosure of which is incorporated by reference.

### FIELD

The present disclosure generally relates to display technology, and more particularly relates to a display device, a method of driving the display device, and an electronic device including the display device.

### INTRODUCTION

An organic light-emitting diode (OLED) display device may include pixels. The pixels may include OLEDs as light-emitting elements and thin film transistors (TFTs). The pixels of the OLED display device may be arranged as a matrix. The OLED display device may adjust the luminance of an image displayed by the pixels based on a gradation of video data.

The display device may include a display panel including the pixels, as well as gate lines and data lines connected to the pixels. Each pixel may be connected to the appropriate gate line and the appropriate data line by a switching element.

When a gate signal changes from a gate-on voltage to a gate-off voltage, a kickback variance might occur in which a gate voltage of a driving transistor is reduced under the influence of a scan signal. Such a kickback variance may cause a gate-source voltage Vgs of the driving transistor to change. For example, if a gate-source voltage of a gate electrode of the driving transistor changes due to a kickback voltage, a current flowing through the driving transistor to an organic light-emitting diode or a sensing line might change unintentionally. Such a kickback variance might cause a luminance deviation among the pixels.

A relatively large storage capacitor may be fabricated at each pixel to address kickback variance and maintain a substantially constant voltage on a charged pixel throughout a frame cycle. Although a large storage capacitor may extend the voltage holding ratio of the pixel and/or reduce a kickback voltage to achieve a desired image quality, such a capacitor may have various disadvantages such as increased transistor load or the like.

### SUMMARY

Embodiments of the present disclosure may provide a display device having substantially uniform luminance.

In an embodiment, a display device includes: a display panel having a first row including a first pixel, the first pixel including at least one first switching transistor and a first driving transistor; a gate driver connected to the display panel through a plurality of gate lines, the gate driver including a logic unit for applying a first gate signal to the first pixel through a gate line corresponding to the first pixel among the plurality of gate lines; and a data driver connected to the display panel through a data line for applying a first data signal to the first pixel, wherein the first gate signal applies a third voltage level to the at least one first switching transistor for a predetermined time period, wherein the third voltage level is an intermediate level voltage between a first voltage level for turning on the at least one first switching transistor and a second voltage level for turning off the at least one first switching transistor.

According to an embodiment, a display device may include: a display panel having a first row including a first pixel, the first pixel including a first driving transistor; a gate driver connected to the display panel through a plurality of gate lines, the gate driver including a logic unit for applying a first gate signal to the first pixel through a gate line corresponding to the first pixel among the plurality of gate lines; and a data driver connected to the display panel through a data line for applying a first data signal to the first pixel. Here, the first gate signal may apply a third voltage level to the first driving transistor for a predetermined time period, where the third voltage level is an intermediate voltage level between a first voltage level for turning on the first driving transistor and a second voltage level for turning off the first driving transistor.

The gate driver may include a gate driving circuit that generates a logic input signal for generating the first gate signal to be applied to a gate of the first driving transistor included in the first pixel.

The logic unit may generate the first gate signal based on the logic input signal, and the first driving transistor may be turned on based on the third voltage level of the first gate signal.

The display panel may include a second pixel connected to a second row adjacent to the first row and including a second driving transistor, the logic unit may apply a second gate signal to the second pixel through a gate line corresponding to the second pixel, and the data driver may transmit the first data signal to the first pixel and to the second pixel through the data line, the first pixel and the second pixel being charged based on the first data signal.

The first gate signal and the second gate signal may transition from the second voltage level to the third voltage level for the predetermined time period and then to the first voltage level.

The first gate signal and the second gate signal may transition from the first voltage level to the third voltage level for the predetermined time period and then to the second voltage level.

According to an embodiment, a display device may include: first pixels arranged in a plurality of odd-numbered rows, each first pixel including a first light-shielding pattern for shielding external light, a first gate electrode of a transistor that is disposed on the first light-shielding pattern and connected to one of a plurality of odd-group gate lines, a first source electrode disposed on the first gate electrode, and a first contact in electrical contact with the first source electrode and the first light-shielding pattern and providing an electrical connection path between the first source electrode and the light-shielding pattern. In addition, the display device may include: second pixels arranged in a plurality of even-numbered rows, each second pixel including a second gate electrode of a transistor that is disposed on the first light-shielding pattern and connected to one of a plurality of even-group gate lines, a second source electrode disposed on the second gate electrode, and a second contact in electrical contact with the second source electrode and the first light-shielding pattern, providing an electrical connection path between the second source electrode and the first light-shielding pattern, and having a quantity of contacts different from that of the first contact.

A first gate signal including an intermediate voltage level voltage may be applied to the pixels connected to the plurality of odd-numbered rows through the first gate electrode, and a second gate signal including the intermediate level voltage may be transmitted to the pixels connected to the plurality of even-numbered rows through the second gate electrode.

The first gate signal and the second gate signal may transition from a low-level voltage to the intermediate level voltage for a predetermined time period and then to a high-level voltage.

The first gate signal and the second gate signal may transition from a high-level voltage to the intermediate level voltage for a predetermined time period and then to a low-level voltage.

The quantity of the first contacts may be less than the quantity of the second contacts.

The first gate signal transmitted to the odd-group gate line may be generated based on a first clock signal, and the second gate signal transmitted to the even-group gate line may be generated based on a second clock signal different from the first clock signal.

The display device may further include: a first transistor including a second light-shielding pattern for shielding external light, a third gate electrode to which the first clock signal is applied, a third source electrode and a third drain electrode, disposed on the third gate electrode, the odd-group gate line disposed on the third drain electrode, and a third contact in electrical contact with the third source electrode and the second light-shielding pattern and providing an electrical connection path between the third source electrode and the second light-shielding pattern. In addition, the display device may include: a second transistor including a fourth gate electrode to which the second clock signal is applied, a fourth source electrode and a fourth drain electrode, disposed on the fourth gate electrode, the even-group gate line disposed on the fourth drain electrode, and a fourth contact in electrical contact with the fourth source electrode and the second light-shielding pattern, providing an electrical connection path between the fourth source electrode and the second light-shielding pattern, and having a quantity of contacts different from the quantity of the third contacts.

The quantity of the third contacts may be less than the quantity of the fourth contacts.

In an embodiment, an electronic device includes: a display module having a first row including a first pixel having at least one first switching transistor and connected to a first row and including a first driving transistor, and generating a first gate signal for applying a third voltage level, which is a mid-level an intermediate voltage level between a first voltage level for turning on the first driving transistor at least one first switching transistor and a second voltage level for turning off the first driving transistor at least one first switching transistor, to the first driving transistor at least one first switching transistor of the first pixel through a gate line corresponding to the first pixel for a predetermined time period; a processor for transmitting a data signal input into the display module; and a power module for supplying power to the display module and the processor.

According to an embodiment, an electronic device may include: a display module having a first row including a first pixel including a first driving transistor, and generating a first gate signal for applying a third voltage level, which is an intermediate voltage level between a first voltage level for turning on the first driving transistor and a second voltage level for turning off the first driving transistor, to the first driving transistor of the first pixel through a gate line corresponding to the first pixel for a predetermined time period; a processor for transmitting a data signal input into the display module; and a power module for supplying power to the display module and the processor.

The display module may generate a logic input signal for generating the first gate signal applied to a gate of the first driving transistor included in the first pixel.

The display module may generate the first gate signal based on the logic input signal, and the first driving transistor may be turned on based on the intermediate level voltage of the first gate signal.

The display module may include a second pixel connected to a second row adjacent to the first row and including a second driving transistor, may generate a second gate signal to the second pixel through a gate line corresponding to the second pixel, and may transmit a first data signal to the first pixel and the second pixel, the first pixel and the second pixel being charged based on the first data signal.

The display module may transition the first gate signal and the second gate signal from the second voltage level to a third voltage level for the predetermined time period and then to the first voltage level.

The display module may transition the first gate signal and the second gate signal from the first voltage level to a third voltage level for the predetermined time period, and then to the second voltage level.

According to an embodiment, luminance deviations may be controlled by reducing the kickback variance of the gate signal. Accordingly, luminance deviations between the adjacent pixels may be precisely controlled.

In addition, according to an embodiment, luminance deviations may be controlled for each region of the display panel. Accordingly, luminance deviations between the central and peripheral pixels may be precisely controlled.

### BRIEF DESCRIPTION OF THE DRAWINGS

FIG. 1 is a block diagram showing a display device according to an embodiment.

FIG. 2 is a block diagram showing a connection configuration between a plurality of pixels and signal lines according to an embodiment.

FIG. 3 is a graphical diagram showing a gate signal according to an embodiment.

FIG. 4 is a graphical diagram showing a gate voltage of a pixel based on the gate signal of FIG. 3 according to an embodiment.

FIG. 5 is a block diagram showing part of the display device of FIG. 1 according to an embodiment.

FIG. 6 is a circuit diagram showing a pixel according to an embodiment.

FIG. 7 is a graphical diagram showing a signal for describing an operation of the pixel in FIG. 6 according to an embodiment.

FIG. 8 is a block diagram showing a first gate driving circuit according to an embodiment.

FIG. 9 is a graphical diagram showing a gate signal according to an embodiment.

FIG. 10 is a cross-sectional diagram showing a display panel including a plurality of pixels connected to an odd-group gate line according to an embodiment.

FIG. 11 is a cross-sectional diagram showing a plurality of pixels connected to an even-group gate line according to an embodiment.

FIG. 12 is a cross-sectional diagram showing a plurality of pixels connected to an odd-group gate line according to a comparative example.

FIG. 13 is a cross-sectional diagram showing an odd-group gate line to which an odd-group gate signal generated based on a first clock signal is applied according to an embodiment.

FIG. 14 is a cross-sectional diagram showing an even-group gate line to which an even-group gate signal generated based on a second clock signal is applied according to an embodiment.

FIG. 15 is a cross-sectional diagram showing an odd-group gate line to which an odd-group gate signal generated based on a first clock signal is applied according to a comparative example.

FIG. 16 is a tabular diagram showing a luminance deviation based on a kickback variance of odd-group gate lines and even-group gate lines connected to the periphery and center of the display panel, respectively.

FIG. 17 is a block diagram showing an electronic device according to an embodiment.

FIG. 18 is a schematic diagram showing an electronic device according to a configurable embodiment.

### DETAILED DESCRIPTION

Hereinafter, illustrative embodiments of the present disclosure are described in detail with reference to the accompanying drawings so that those skilled in the art to which the present disclosure pertains may easily practice the invention. However, embodiments of the present disclosure may be modified in various ways, and are not limited to the illustrative embodiments provided herein.

In addition, in the drawings, portions unrelated to the associated description may be omitted to clearly illustrate pertinent elements of the present disclosure, and similar elements or portions may be denoted by similar reference numerals throughout the specification.

Further, a term of a singular number may be interpreted as the singular number or its plural number unless explicitly expressed such as “one” or “single.”

Terms including ordinal numbers such as “first”, “second”, and the like may be used to describe various components. However, the order of these components is not limited by these terms. Such a term is used to distinguish one component from another component.

Hereinafter, illustrative embodiments of the present disclosure are described in detail. However, it should be noted that the following description is provided by way of example, and is not intended to limit the scope of the present disclosure.

In an embodiment, a gate signal applied to a gate line for at least one switching transistor of a display pixel may have an intermediate voltage level for a predetermined period of time before fully transitioning between on and off voltage levels to control a kickback variation at the transistor. The kickback variation may be further controlled by adjusting the number of contacts in the gate line. For example, a gate signal applied to a gate line for a data line switching transitory connected to a gate of a driving transistor for a display pixel may have an intermediate voltage level for a predetermined period of time before fully transitioning between on and off voltage levels to minimize a kickback variation in the current through the driving transistor, without limitation thereto.

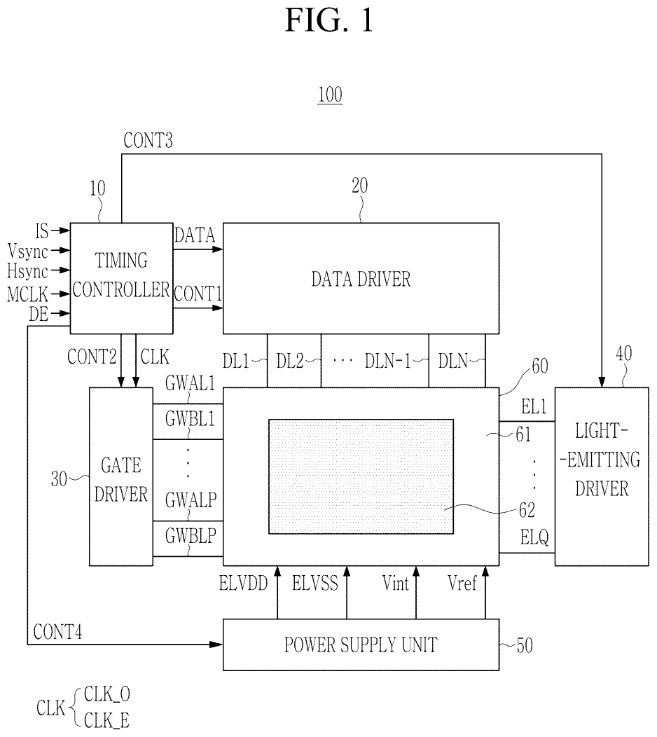

As shown in FIG. 1, a display device, according to an embodiment, is indicated generally by the reference numeral 100.

The display device 100 may include a timing controller 10, a data driver 20, a gate driver 30, a light-emitting driver 40, a power supply unit 50, and a display panel 60.

The timing controller 10 may sequentially receive an image signal IS input from the outside. The image signal IS may include luminance information distinguished by a gradation of each of a plurality of pixels included in the display panel 60. The timing controller 10 may receive a display interface signal that controls display of the image signal IS. The display interface signal may include a vertical data synchronization signal Vsync, a horizontal data synchronization signal Hsync, a main clock signal MCLK, and a data enable signal DE.

The timing controller 10 may generate a plurality of control signals CONT1, CONT2, CONT3, and CONT4, a clock signal CLK, and an image data signal DATA based on the image signal IS and the display interface signal. The image data signal DATA may be generated through image processing such as gamma correction and/or luminance compensation for the image signal IS.

The timing controller 10 may generate the clock signal CLK as a plurality of clock signals CLK having different frequencies based on the main clock signal MCLK. For example, the timing controller 10 may generate the plurality of clock signals CLK using a divider circuit. The plurality of clock signals CLK may include an odd or first clock signal CLK_O and an even or second clock signal CLK_E. A frequency of the second clock signal CLK_E may be different from a frequency of the first clock signal CLK_O.

The timing controller 10 may transmit, to the gate driver 30, the control signal CONT2 that controls an operation of the gate driver 30, and the plurality of clock signals CLK including the first clock signal CLK_O and the second clock signal CLK_E. The gate driver 30 may generate odd-group gate signals provided to odd-group gate lines GWAL1 to GWALP, where P is an integer greater than one, based on the first clock signal CLK_O. The gate driver 30 may generate even-group gate signals provided to even-group gate lines GWBL1 to GWBLP based on the second clock signal CLK_E.

The timing controller 10 may transmit, to the data driver 20, the image data signal DATA and the control signal CONT1 that controls an operation of the data driver 20. The timing controller 10 may transmit, to the light-emitting driver 40, the control signal CONT3 that controls an operation of the light-emitting driver 40. The timing controller 10 may transmit, to the power supply unit 50, the control signal CONT4 that controls an operation of the power supply unit 50.

The data driver 20 may sample the image data signal DATA based on the control signal CONT1. The data driver 20 may determine gradation voltages to be transmitted to the plurality of pixels based on the image data signal DATA. The data driver 20 may transmit the gradation voltage as a data signal to each of a plurality of data lines DL1 to DLN.

The gate driver 30 may generate the odd-group gate signal based on the control signal CONT2 and the first clock signal CLK_O. The gate driver 30 may sequentially transmit the odd-group gate signals to the odd-group gate lines GWAL1 to GWALP. The odd-group gate lines GWAL1 to GWALP may be connected to the plurality of pixels corresponding to odd-numbered rows of the display panel 60, respectively.

The gate driver 30 may generate the even-group gate signal based on the control signal CONT2 and the second clock signal CLK_E. The gate driver 30 may sequentially transmit the even-group gate signals to the even-group gate lines GWBL1 to GWBLP. The even-group gate lines GWBL1 to GWBLP may be connected to the plurality of pixels corresponding to even-numbered rows of the display panel 60, respectively.

The gate driver 30 may be connected to the display panel 60 through the pluralities of gate lines GWAL1 to GWALP and GWBL1 to GWBLP.

The light-emitting driver 40 may generate a light-emitting control signal based on the control signal CONT3. The light-emitting control signal may include a light-emitting start signal, a light-emitting clock signal, and a holding control signal. The light-emitting start signal is a signal for generating a first light-emitting control signal for displaying one frame of an image. The light-emitting clock signal is a synchronous signal for transmitting the first light-emitting control signal to a plurality of light-emitting control lines EL1 to ELQ, where Q is an integer substantially equal to two times P or the total number of pixel rows in the display panel. The holding control signal is a signal for controlling the light-emitting driver 40 for the light-emitting driver 40 to maintain the first light-emitting signal output during low-frequency driving, such as for lower frequency operation of the even-numbered pixel rows than of the odd-numbered pixel rows, without limitation thereto.

The power supply unit 50 may generate voltages for driving the plurality of pixels based on the control signal CONT4. The power supply unit 50 may generate a driving voltage ELVDD and a common voltage ELVSS, and supply these voltages to the plurality of pixels. The driving voltage ELVDD may be a relatively high-level voltage provided to an anode of a light-emitting diode included in the pixel. The common voltage ELVSS may be a relatively low-level voltage provided to a cathode of the light-emitting diode included in the pixel.

The power supply unit 50 may generate an initialization voltage Vint and a reference voltage Vref, and supply these voltages to the display panel including the plurality of pixels. The initialization voltage Vint may be a relatively low-level voltage provided to the anode of the light-emitting diode included in the pixel. The reference voltage Vref may be a voltage provided to a gate terminal of the driving transistor.

A voltage level of the driving voltage ELVDD may be higher than a voltage level of the common voltage ELVSS. A voltage level of the initialization voltage Vint may be lower than the voltage level of the common voltage ELVSS. A voltage level of the reference voltage Vref may be lower than a voltage level of the driving voltage ELVDD and higher than the voltage level of the common voltage ELVSS.

The display panel 60 may include the plurality of data lines DL1 to DLN, the plurality of odd-group gate lines GWAL1 to GWALP, the plurality of even-group gate lines GWBL1 to GWBLP, and the plurality of light-emitting control lines EL1 to ELQ. The display panel 60 may include the plurality of pixels connected to a plurality of signal lines and disposed in a matrix arrangement. Each of the plurality of pixels may be provided with the driving voltage ELVDD, the common voltage ELVSS, the initialization voltage Vint, and the reference voltage Vref from the power supply unit 50.

The display panel 60 may include a periphery 61 and a center 62. The center 62 may be substantially disposed at the center of the display panel 60. The periphery 61 may surround the center 62 and be substantially disposed on the outside of the display panel 60. The odd-group gate lines GWAL1 to GWALP and the even-group gate lines GWBL1 to GWBLP connected to the periphery 61 and the center 62 may be different from each other. The plurality of data lines DL1, DL2, . . . , DLN-1, and DLN respectively connected to the periphery 61 and the center 62 may be different from each other.

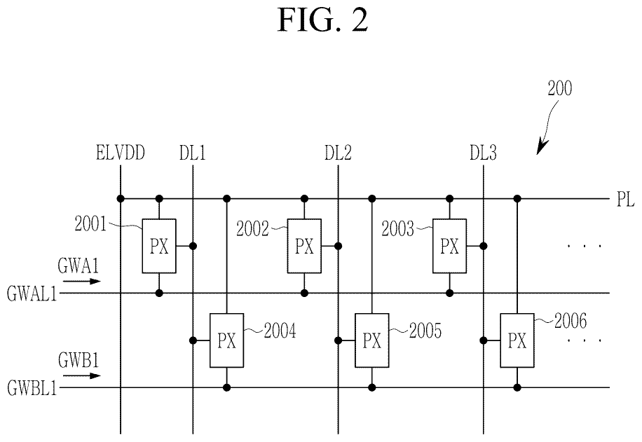

Turning to FIG. 2, a display panel connection configuration between the plurality of pixels and the signal lines, according to an embodiment, is indicated generally by the reference numeral 200.

For example, FIG. 2 shows some pixels connected to the odd-group gate lines GWAL1 to GWALP (see FIG. 1) and other pixels connected to the even-group gate lines GWBL1 to GWBLP (see FIG. 1) within the display panel 60. For convenience of description, FIG. 2 shows those pixels connected to the odd-group gate line GWAL1 disposed on an odd-numbered row (e.g., first row) of the display panel 60 and those pixels connected to the even-group gate line GWBL1 disposed on an even-numbered row (e.g., second row) thereof.

Referring to FIG. 2, a plurality of pixels 2001, 2002, 2003, 2004, 2005, and 2006 may include a plurality of first color pixels 2001 and 2005, a plurality of second color pixels 2003 and 2004, and a plurality of third color pixels 2002 and 2006. Each of the first color pixels 2001 and 2005, the second color pixels 2003 and 2004, and the third color pixels 2002 and 2006 may be implemented to have the same color as each other, respectively. However, the first color pixels 2001 and 2005, the second color pixels 2003 and 2004, and the third color pixels 2002 and 2006 may be implemented to have different colors from each other, respectively. For example, the plurality of first color pixels 2001 and 2005 may be implemented to have red. The plurality of second color pixels 2003 and 2004 may be implemented to have green. The plurality of third color pixels 2002 and 2006 may be implemented to have blue.

In an alternate embodiment, the plurality of first color pixels 2001 and 2005 may be implemented to emit light red and dark red, respectively. The plurality of second color pixels 2003 and 2004 may be implemented to emit dark green and light green, respectively. The plurality of third color pixels 2002 and 2006 may be implemented to emit light blue and dark blue, respectively.

The pixels implemented to have different colors may be connected to one data line. For example, the first color pixel 2001 and the second color pixel 2004 may be connected to the first data line DL1. The third color pixel 2002 and the first color pixel 2005 may be connected to the second data line DL2. The second color pixel 2003 and the third color pixel 2006 may be connected to the third data line DL3. The plurality of pixels 2001 to 2006 may receive the driving voltage ELVDD through a voltage line PL.

The odd-group gate line GWAL1 may be connected to the plurality of pixels 2001, 2002, and 2003 disposed on the first row of the display panel 60 (see FIG. 1). The plurality of pixels 2001, 2002, and 2003 may receive the odd-group gate signal GWA1 through the odd-group gate line GWAL1.

The even-group gate line GWBL1 may be connected to the plurality of pixels 2004, 2005, and 2006 disposed on the second row of the display panel 60. The plurality of pixels 2004, 2005, and 2006 may receive the even-group gate signal GWB1 through the even-group gate line GWBL1.

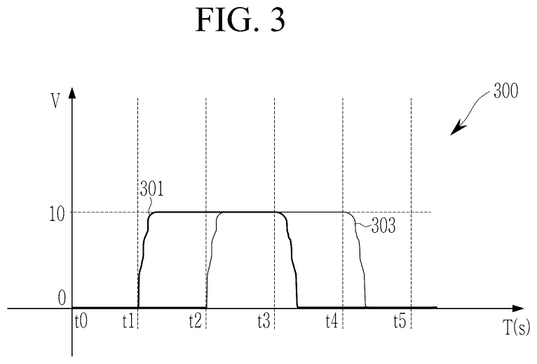

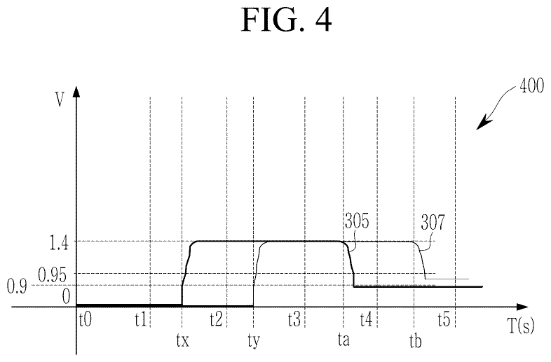

As shown in FIG. 3 and FIG. 4, the gate signal is indicated generally by the reference numeral 300, and a gate voltage of the pixel based on the gate signal is indicated generally by the reference numeral 400.

Referring to FIGS. 2 to 4, the plurality of pixels 2001 to 2003 may receive an odd-group gate signal 301 through the odd-group gate line GWAL1. The plurality of pixels 2004 to 2006 may receive an even-group gate signal 303 through the even-group gate line GWBL1. Each of the odd-group gate signal 301 and the even-group gate signal 303 may have a first high-level voltage, for example, about 10 V, for a predetermined time period.

From t0 to t1, each of the odd-group gate signal 301 and the even-group gate signal 303 may have a first low-level voltage, for example, about zero V. At t1, the odd-group gate signal 301 may transition from the first low-level voltage to the first high-level voltage. From t0 to tx, a gate voltage 305 of the driving transistor included in each of the plurality of pixels 2001 to 2003 that receive the odd-group gate signal 301 may have a second low-level voltage, for example, about 0.6 V. At tx, the gate voltage 305 of the driving transistor included in each of the plurality of pixels 2001 to 2003 may transition from the second low-level voltage to a second high-level voltage, for example, about 1.4 V.

At t2, the even-group gate signal 303 may transition from the first low-level voltage to the first high-level voltage. From t0 to ty, a gate voltage 307 of the driving transistor included in each of the plurality of pixels 2004 to 2006 that receive the even-group gate signal 303 may have the second low-level voltage.

At ty, the gate voltage 307 of the driving transistor included in each of the plurality of pixels 2004 to 2006 may transition from the second low-level voltage to the second high-level voltage.

After transitioning to the first high-level voltage, the odd-group gate signal 301 may maintain the first high-level voltage until t3. The gate voltage 305 of the driving transistor included in each of the plurality of pixels 2001 to 2003 may maintain the second high-level voltage until ta. At t3, the odd-group gate signal 301 may transition from the first high-level voltage to the first low-level voltage. The odd-group gate signal 301 may have the first low-level voltage until t5. At ta, the gate voltage 305 of the driving transistor included in each of the plurality of pixels 2001 to 2003 may transition from the second high-level voltage to a first intermediate-level voltage, for example, about 0.9 V. The gate voltage 305 of the driving transistor included in each of the plurality of pixels 2001 to 2003 may have the first intermediate-level voltage until t5.

After transitioning to the first high-level voltage, the even-group gate signal 303 may maintain the first high-level voltage until t4. The gate voltage 307 of the driving transistor included in each of the plurality of pixels 2004 to 2006 may maintain the second high-level voltage until tb. At t4, the even-group gate signal 303 may transition from the first high-level voltage to the first low-level voltage. The even-group gate signal 303 may have the first low-level voltage until t5. At tb, the gate voltage 307 of the driving transistor included in each of the plurality of pixels 2004 to 2006 may transition from the second high-level voltage to a second intermediate-level voltage, for example, about 0.95 V. The gate voltage 307 of the driving transistor included in each of the plurality of pixels 2004 to 2006 may have the second intermediate-level voltage until t5.

In the period after tb, the gate voltage 305 of the driving transistor included in each of the plurality of odd-group pixels 2001 to 2003 and the gate voltage 307 of the driving transistor included in each of the plurality of even-group pixels 2004 to 2006 may be different from each other.

When each of the odd-group gate signal 301 and the even-group gate signal 303 transitions from the first high-level voltage to the first low-level voltage, a kickback variance might occur in each of the plurality of pixels 2001 to 2003 and the plurality of pixels 2004 to 2006.

The kickback or kickback variance may refer to a phenomenon in which a charging voltage of a pixel connected to a target gate line is reduced by the gate signal applied to the gate line adjacent to the target gate line when the gate signal applied to the adjacent gate line transitions from a high level to a low level, without limitation thereto.

For example, at a falling edge of the odd-group gate signal 301, charging voltages of the plurality of pixels 2001 to 2003 that receive the odd-group gate signal 301 may be reduced due to an effect of the even-group gate signal 303. When the odd-group gate signal 301 transitions from the high level to the low level, the plurality of pixels 2004 to 2006 may already be charged by the even-group gate signal 303. Accordingly, each charging voltage of the plurality of pixels 2001 to 2003 that receive the odd-group gate signal 301 may be the first intermediate-level voltage. On the other hand, when the even-group gate signal 303 transitions from the first high-level voltage to the first low-level voltage, the odd-group gate signal 301 may be the first low-level voltage. Accordingly, each charging voltage of the plurality of pixels 2004 to 2006 that receive the even-group gate signal 303 may be the second intermediate-level voltage.

For example, in the period after tb, each charging voltage of the plurality of pixels 2001 to 2003 may be lower than each charging voltage of the plurality of pixels 2004 to 2006.

Kickback variance of the plurality of pixels 2001 to 2003 and kickback variance of the plurality of pixels 2004 to 2006 may be different from each other, and magnitudes of the charging voltages may thus be different from each other. Accordingly, a luminance deviation might otherwise occur between the plurality of pixels 2001 to 2003 and the plurality of pixels 2004 to 2006.

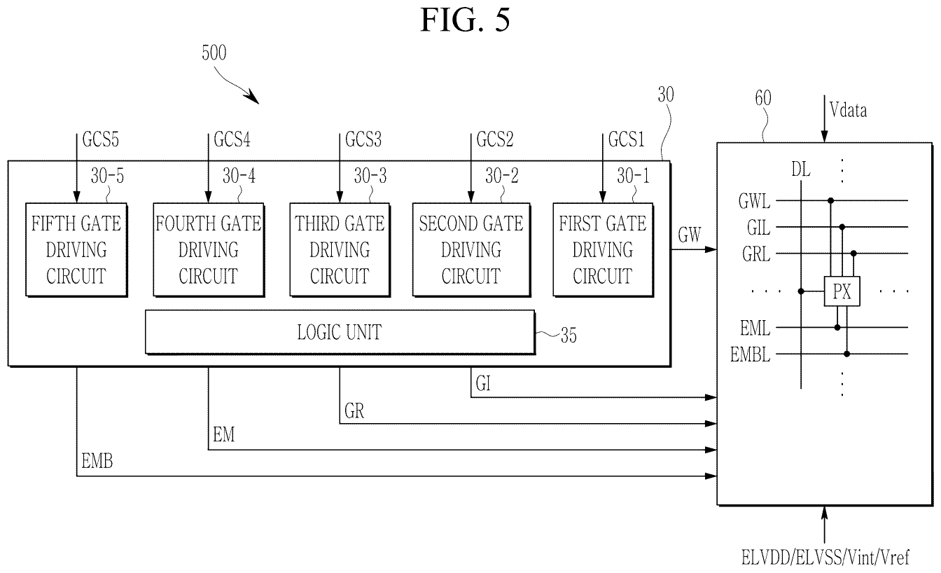

Turning to FIG. 5, a part of the display device, according to an embodiment, is indicated generally by the reference numeral 500.

For example, FIG. 5 shows an embodiment of the gate driver 30 generating the plurality of gate signals and transmitting the plurality of gate signals to the display panel.

Referring to FIG. 5, first to fifth gate driving circuits of the gate driver 30 may receive first to fifth control signals GCS1 to GCS5, respectively, from a timing controller 10 (see FIG. 1). The first to fifth control signals GCS1 to GCS5 may be included in the control signal CONT2 (see FIG. 1).

The gate driver 30 may include a plurality of gate driving circuits 30-1, 30-2, 30-3, 30-4, and 30-5. The plurality of gate driving circuits 30-1, 30-2, 30-3, 30-4, and 30-5 may receive the first to fifth control signals GCS1 to GCS5, respectively. The plurality of gate driving circuits 30-1, 30-2, 30-3, 30-4, and 30-5 may generate first to fifth gate signals GW, GI, GR, EM, and EMB based on the first to fifth control signals GCS1 to GCS5, respectively.

A plurality of pixels PX included in the display panel 60 may be connected to each of the plurality of gate lines. The plurality of gate lines may include a first gate line GWL connected to the first gate driving circuit 30-1, a second gate line GIL connected to the second gate driving circuit 30-2, a third gate line GRL connected to the third gate driving circuit 30-3, a fourth gate line EML connected to the fourth gate driving circuit 30-4, and a fifth gate line EMBL connected to the fifth gate driving circuit 30-5.

The first gate driving circuit 30-1 may sequentially supply the first gate signal GW to the first gate line GWL based on the first control signal GCS1. The second gate driving circuit 30-2 may sequentially supply the second gate signal GI to the second gate line GIL based on the second control signal GCS2. The third gate driving circuit 30-3 may sequentially supply the third gate signal GR to the third gate line GRL based on the third control signal GCS3. The fourth gate driving circuit 30-4 may sequentially supply the fourth gate signal EM to the fourth gate line EML based on the fourth control signal GCS4. The fifth gate driving circuit 30-5 may sequentially supply the fifth gate signal EMB to the fifth gate line EMBL based on the fifth control signal GCS5.

The gate driver 30 may include a logic unit 35, which may be connected to the plurality of gate driving circuits 30-1, 30-2, 30-3, 30-4, and 30-5. The logic unit 35 may receive the plurality of gate signals GW, GI, GR, EM, and EMB from the plurality of gate driving circuits 30-1, 30-2, 30-3, 30-4, and 30-5, respectively; and may adjust voltage magnitudes of the plurality of gate signals GW, GI, GR, EM, and EMB for output to the display panel 60. For example, the logic unit 35 may adjust the plurality of gate signals GW, GI, GR, EM, and EMB to transition via a first intermediate level voltage, which is a voltage between a low-level voltage and a high-level voltage, when the plurality of gate signals GW, GI, GR, EM, and EMB transition from the low-level voltage to the high-level voltage. For example, if the low-level voltage is about −6 V and the high-level voltage is about 11 V, the intermediate level voltage may be about −3 V, without limitation thereto.

Similarly, the logic unit 35 may adjust the plurality of gate signals GW, GI, GR, EM, and EMB for the signals to transition through a second intermediate level voltage, which is a voltage between the high-level voltage and the low-level voltage, when the plurality of gate signals GW, GI, GR, EM, and EMB transition from the high-level voltage to the low-level voltage. The first and second intermediate level voltages may be the same, without limitation thereto. For example, the second intermediate level voltage may be about 8 V.

The data driver 20 (see FIG. 1) may convert the image data signal DATA received from the timing controller 10 into a data signal Vdata in the form of a voltage, or in an alternate embodiment, in the form of a current. The data driver 20 may apply the data signal Vdata representing the gradation to the plurality of data lines DL1 to DLN (see FIG. 1) based on the control signal CONT1.

The power supply unit 50 (see FIG. 1) may supply the driving voltage ELVDD, the common voltage ELVSS, the initialization voltage Vint, and the reference voltage Vref to each of the plurality of pixels PX based on the control signal CONT4 (see FIG. 1).

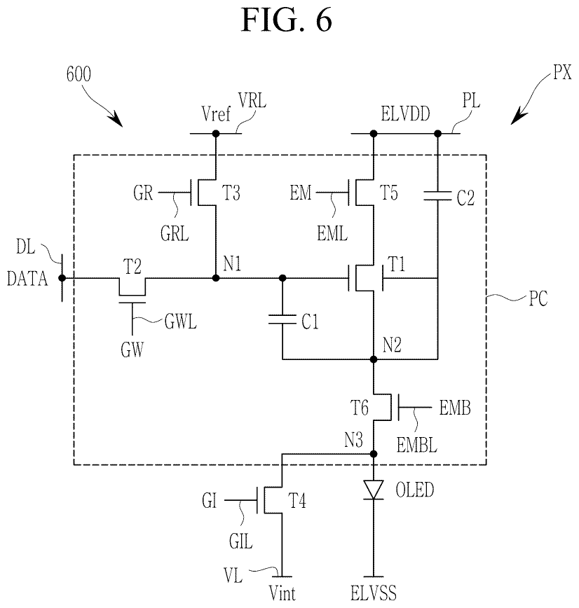

Turning now to FIG. 6, a pixel with associated circuitry, according to an embodiment, is indicated generally by the reference numeral 600.

Referring to FIG. 6, a pixel PX may include a pixel circuit PC and an organic light-emitting diode (OLED) connected to the pixel circuit PC.

The pixel PX may be connected to the first gate line GWL for receiving the first gate signal GW, the second gate line GIL for receiving the second gate signal GI, the third gate line GRL for receiving the third gate signal GR, the fourth gate line EML for receiving the fourth gate signal EM, the fifth gate line EMBL for receiving the fifth gate signal EMB, and the data line DL for receiving the data signal.

The pixel PX may be connected to the voltage line PL for receiving the driving voltage ELVDD, a reference voltage line VRL for receiving the reference voltage Vref, and an initialization voltage line VL for receiving the initialization voltage Vint.

A plurality of transistors included in the pixel circuit PC may be N-type oxide thin film transistors. An oxide thin film transistor may be a low-temperature polycrystalline oxide (LTPO) thin film transistor where its semiconductor layer includes an oxide. However, the plurality of N-type transistors is not limited thereto. For example, the semiconductor layer included in the N-type transistor may include an inorganic semiconductor (e.g., amorphous silicon or polycrystalline silicon) or an organic semiconductor.

The pixel circuit PC may include first to sixth transistors T1 to T6, as well as first and second capacitors C1 and C2. The first transistor T1 may be a driving transistor that outputs a driving current corresponding to the data signal DATA, and the second to sixth transistors T2 to T6 may be switching transistors that transmit signals.

The first or second terminal or electrode of each of the first to sixth transistors T1 to T6 may be a source or a drain depending on a voltage at the first or second terminal. For example, the second terminal may be the source if the first terminal is the drain, and the second terminal may be the drain if the first terminal is the source.

The first transistor T1 may be connected between the voltage line PL and a second node N2. The first transistor T1 may include the first terminal connected to the fifth transistor T5, the second terminal connected to the second node N2, and a gate connected to a first node N1. Hereinafter, the first transistor T1 may be referenced as the driving transistor.

The first terminal of the first transistor T1 may be connected to the voltage line PL via the fifth transistor T5. The first terminal of the first transistor T1 may be connected to the second terminal of the fifth transistor T5.

The second terminal of the first transistor T1 may be connected to the first terminal of the sixth transistor T6, the first capacitor C1, and the second capacitor C2. The second terminal of the first transistor T1 may be connected to a pixel electrode of the organic light-emitting diode (OLED) through the sixth transistor T6.

The gate of the first transistor T1 may be connected to the second terminal of the second transistor T2, the second terminal of the third transistor T3, and the first capacitor C1. The first transistor T1 may control an amount of driving current flowing through the organic light-emitting diode (OLED) by receiving the data signal DATA based on a switching operation of the second transistor T2.

The second transistor T2 may include a gate connected to the first gate line GWL, a first terminal connected to the data line DL, and a second terminal connected to the first node N1. The second terminal of the second transistor T2 may be connected to the gate of the first transistor T1, the second terminal of the third transistor T3, and the first capacitor C1. The second transistor T2 may be turned on by the first gate signal GW transmitted to the first gate line GWL supplying the first, second and third voltage levels. The data signal DATA transmitted to the data line DL may be transmitted to the first node N1 through the turned-on second transistor T2.

The third transistor T3 may include a gate connected to the third gate line GRL, the first terminal connected to the first node N1, and the second terminal connected to the reference voltage line VRL. The first terminal of the third transistor T3 may be connected to the gate of the first transistor T1, the second terminal of the second transistor T2, and the first capacitor C1. The third transistor T3 may be turned on by the third gate signal GR transmitted to the third gate line GRL supplying the first, second and third voltage levels. The reference voltage Vref transmitted to the reference voltage line VRL may be transmitted to the first node N1 through the turned-on third transistor T3.

The fourth transistor T4 may include a gate connected to the second gate line GIL, the first terminal connected to a third node N3, and the second terminal connected to the initialization voltage line VL. The first terminal of the fourth transistor T4 may be connected to the second terminal of the sixth transistor T6 and the organic light-emitting diode (OLED). The fourth transistor T4 may be turned on by the second gate signal GI transmitted to the second gate line GIL supplying the first, second and third voltage levels. The initialization voltage Vint transmitted to the initialization voltage line VL may be transmitted to the third node N3 through the turned-on fourth transistor T4.

The fifth transistor T5 may include a gate connected to the fourth gate line EML, the first terminal connected to the voltage line PL, and the second terminal connected to the first terminal of the first transistor T1. The fifth transistor T5 may be turned on based on the fourth gate signal EM transmitted to the fourth gate line EML supplying the first, second and third voltage levels. The driving voltage ELVDD transmitted to the voltage line PL may be transmitted to the first terminal of the first transistor T1 through the turned-on fifth transistor T5.

The sixth transistor T6 may include a gate connected to the fifth gate line EMBL, the first terminal connected to the second node N2, and the second terminal connected to the third node N3. The first terminal of the sixth transistor T6 may be connected to the second terminal of the first transistor T1, the first capacitor C1, and the second capacitor C2. The second terminal of the sixth transistor T6 may be connected to the first terminal of the fourth transistor T4 and the pixel electrode of the organic light-emitting diode (OLED). The sixth transistor T6 may be turned on based on the fifth gate signal EMB transmitted to the fifth gate line EMBL supplying the first, second and third voltage levels.

The first capacitor C1 may be connected between the gate of the first transistor T1 and the second terminal of the first transistor T1. The first electrode of the first capacitor C1 may be connected to the first node N1, and the second electrode may be connected to the second node N2. The first electrode of the first capacitor C1 may be connected to a first gate of the first transistor T1, the second terminal of the second transistor T2, and the first terminal of the third transistor T3. The second electrode of the first capacitor C1 may be connected to the second terminal of the first transistor T1, the second electrode of the second capacitor C2, and the first terminal of the sixth transistor T6. The first capacitor C1 is a storage capacitor, and may store a threshold voltage of the first transistor T1 and a voltage corresponding to the data signal DATA. The first capacitor may have a relatively small capacitance because of the logic unit controlling the kickback variations using the first, second and third voltage levels.

The second capacitor C2 may be connected between the voltage line PL and the second node N2. The first electrode of the second capacitor C2 may be connected to the voltage line PL. The second electrode of the second capacitor C2 may be connected to the second terminal of the first transistor T1, the second electrode of the first capacitor C1, and the first terminal of the sixth transistor T6. Moreover, the capacitance of the second capacitor C2 may be even smaller than a capacitance of the first capacitor C1.

The organic light-emitting diode (OLED) may be connected to the first transistor T1 through the sixth transistor T6. The organic light-emitting diode (OLED) may include the pixel electrode (anode) connected to the third node N3 and a counter electrode (cathode) facing the pixel electrode. The counter electrode may receive the common voltage ELVSS. The counter electrode may be a common electrode common to the plurality of pixels PX.

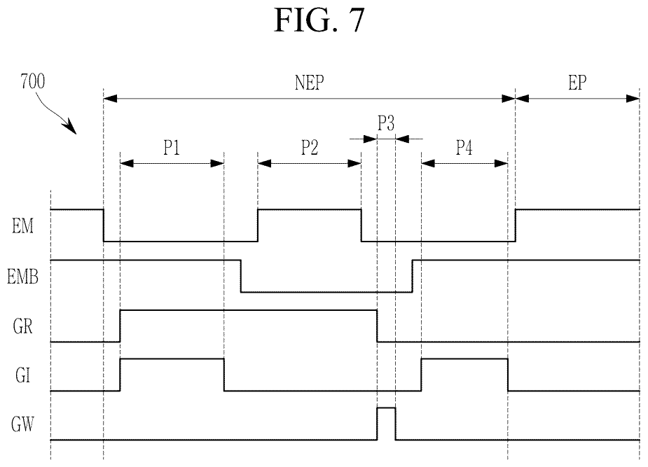

As shown in FIG. 7, a signal for describing an operation of the pixel in FIG. 6 is indicated generally by the reference numeral 700.

Referring to FIG. 7, one frame may include a non light-emitting period NEP in which the pixel PX emits no light, followed by a light-emitting period EP in which the pixel PX emits light. The non light-emitting period NEP may include a first period P1, a second period P2, a third period P3, and a fourth period P4, without limitation thereto.

Each of the first gate signal GW, the second gate signal GI, the third gate signal GR, the fourth gate signal EM, and the fifth gate signal EMB may have the high-level voltage (e.g., first-level voltage) in some periods and the low-level voltage (e.g., second-level voltage) in other periods. Here, the high-level voltage may be a gate-on voltage level sufficient to turn the transistor on, and the low-level voltage may be a gate-off voltage level sufficient to turn the transistor off.

The first period P1 may be a first initialization period during which initialization is performed on the first node N1 to which the first gate of the first transistor T1 is connected and the third node N3 to which the pixel electrode of the organic light-emitting diode (OLED) is connected. In the first period P1, the second gate signal GI of the gate-on voltage level may be supplied to the second gate line GIL, the third gate signal GR of the gate-on voltage level may be supplied to the third gate line GRL, and the fifth gate signal EMB of the gate-on voltage level may be supplied to the fifth gate line EMBL. In the first period P1, the first gate signal GW and the fourth gate signal EM may be supplied at the gate-off voltage level.

The sixth transistor T6 may be turned on by the fifth gate signal EMB, the fourth transistor T4 may be turned on by the second gate signal GI, and the third transistor T3 may be turned on by the third gate signal GR. The gate of the first transistor T1 may be initialized to the reference voltage Vref by the turned-on third transistor T3. The second terminal of the first transistor T1 and the pixel electrode of the organic light-emitting diode (OLED) may be initialized to the initialization voltage Vint by the turned-on sixth transistor T6 and the turned-on fourth transistor T4.

The second period P2 may be a compensation period that compensates for the threshold voltage of the first transistor T1. In the second period P2, the third gate signal GR of the gate-on voltage level may be supplied to the third gate line GRL, and the fourth gate signal EM of the gate-on voltage level may be supplied to the fourth gate line EML. The first gate signal GW, the second gate signal GI, and the fifth gate signal EMB may be supplied at the gate-off voltage level.

The third transistor T3 may be turned on by the third gate signal GR, and the fifth transistor T5 may be turned on by the fourth gate signal EM. Accordingly, the reference voltage Vref may be supplied to the first node N1, and the driving voltage ELVDD may be supplied to the first terminal of the first transistor T1, and the first transistor T1 may thus be turned on. The first transistor T1 may be turned off when the voltage level at the second terminal of the first transistor T1 drops to a difference Vref-Vth between the reference voltage Vref and a threshold voltage Vth of the first transistor T1 or below. The first capacitor C1 may store a voltage corresponding to the threshold voltage Vth of the first transistor T1, thus compensating for the threshold voltage Vth of the first transistor T1.

The third period P3 may be a write period in which the data signal is supplied to the pixel. In the third period P3, the first gate signal GW of the gate-on voltage level may be supplied to the first gate line GWL. The second gate signal GI, the third gate signal GR, the fourth gate signal EM, and the fifth gate signal EMB may be supplied at the gate-off voltage level.

The second transistor T2 may be turned on by the first gate signal GW. The turned-on second transistor T2 may transmit the data signal DATA from the data line DL to the first node N1, that is, to the first gate of the first transistor T1. Accordingly, a voltage at the first node N1 may be changed from the reference voltage Vref to the voltage corresponding to the data signal DATA. Here, a voltage at the second node N2 may also be changed in response to a voltage change at the first node N1. The voltage at the second node N2 may be a voltage Vref−Vth+α×(DATA−Vref) that is changed based on a capacitance ratio α=C1/(C1+C2) of the first capacitor C1 to the second capacitor C2. Accordingly, the first capacitor C1 may be charged by the threshold voltage Vth of the first transistor T1 and the voltage corresponding to the data signal DATA.

The fourth period P4 may be a second initialization period that initializes the second node N2, to which the second terminal of the first transistor T1 is connected, and the third node N3, to which the pixel electrode of the organic light-emitting diode (OLED) is connected, before the light-emitting period EP after the data is written. The second gate signal GI of the gate-on voltage level may be supplied to the second gate line GIL, and the fifth gate signal EMB of the gate-on voltage level may be supplied to the fifth gate line EMBL. In addition, the first gate signal GW, the third gate signal GR, and the fourth gate signal EM may be supplied at the gate-off voltage level.

The fourth transistor T4 may be turned on by the second gate signal GI, and the sixth transistor T6 may be turned on by the fifth gate signal EMB. The initialization voltage Vint may be transmitted to the pixel electrode of the organic light-emitting diode (OLED) by the turned-on fourth transistor T4, and the second node N2 and the third node N3 may share charges by the turned-on sixth transistor T6.

The light-emitting period EP may be a period in which the organic light-emitting diode (OLED) emits light. In the light-emitting period EP, the fourth gate signal EM of the gate-on voltage level may be supplied to the fourth gate line EML, and the fifth gate signal EMB of the gate-on voltage level may be supplied to the fifth gate line EMBL. Each of the first gate signal GW, the second gate signal GI, and the third gate signal GR may have the gate-off voltage level.

The fifth transistor T5 may be turned on by the fourth gate signal EM, and the first driving voltage ELVDD may be supplied to the first terminal of the first transistor T1 by the turned-on fifth transistor T5. The first transistor T1 may output a driving current Id∝Vgs−Vth2 having a magnitude corresponding to a voltage level of the data signal DATA stored in the first capacitor C1, such as a voltage Vgs−Vth acquired by subtracting the threshold voltage Vth of the first transistor T1 from a gate-source voltage Vgs of the first transistor T1. For example, the driving current may flow to the organic light-emitting diode (OLED) through the sixth transistor T6, which is turned on by the fifth gate signal EMB, and the organic light-emitting diode (OLED) may emit light at a luminance corresponding to the magnitude of the driving current.

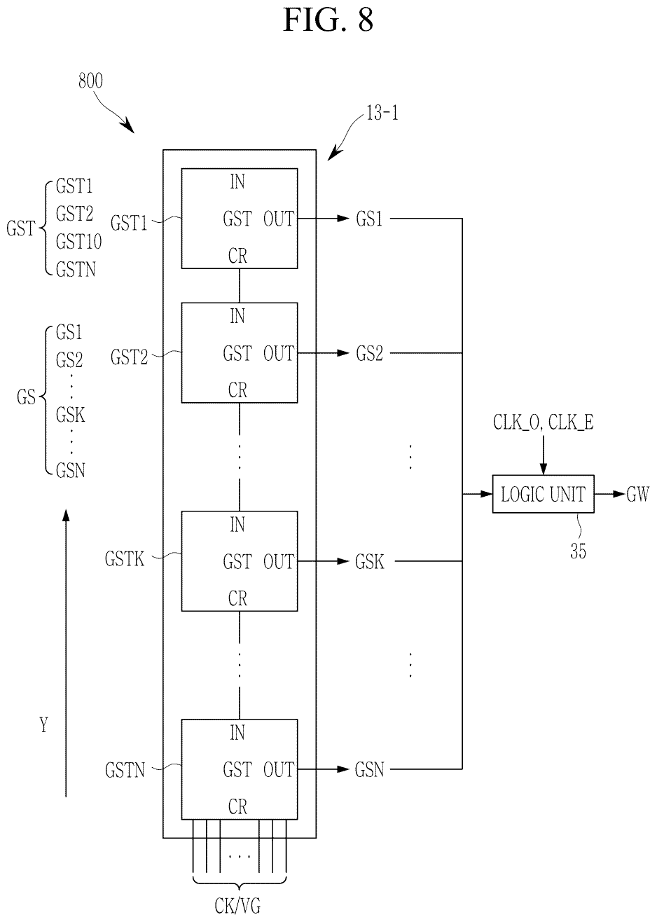

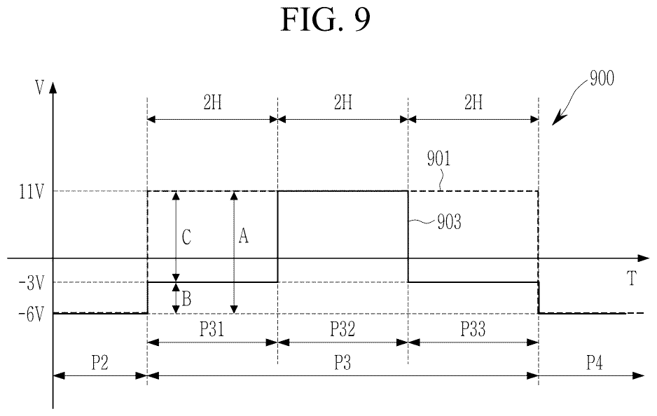

Turning to FIG. 8, the first gate driving circuit, according to an embodiment, is indicated generally by the reference numeral 800. Turning also to FIG. 9, the gate signal, according to an embodiment, is indicated generally by the reference numeral 900.

Referring to FIG. 8, a first gate driving circuit 13-1 may include a plurality of stages GST arranged in a y direction, such as a column direction. The first gate driving circuit 13-1 may drive the plurality of stages GST based on the control signal CONT2, including a start signal STP. The plurality of stages GST may be connected to each other in the form of a shift register, without limitation thereto. A plurality of logic input signals GS may be generated by sequentially transmitting a turn-on level pulse of the start signal STP, as supplied to the first stage GST1, to the next stage GST2. The plurality of stages GST may generate the plurality of logic signals GS based on the start signal or the output signal of the previous stage GST. For example, the logic input signal GS generated at the previous stage may be supplied to the next stage.

The plurality of stages GST may generate the plurality of logic input signals GS based on the clock signal CLK and a voltage signal VG, respectively. The voltage signal VG may be generated by a separate voltage source and applied to each of the plurality of stages GST.

The plurality of stages GST may transmit the plurality of logic input signals GS to the logic unit 35, respectively. The logic unit 35 may output the plurality of gate signals GW, GI, GR, EM, and EMB (see FIG. 6) based on the clock signal CLK and the plurality of logic input signals GS. However, for the convenience of description, the following description is provided assuming that the logic unit 35 outputs the first gate signal GW based on the clock signal CLK and the plurality of logic input signals GS.

Referring to FIG. 9 together, the first gate signal GW may transition from the low-level voltage to the intermediate level voltage for the predetermined time period and then to the high-level voltage. The first gate signal GW may transition from the high-level voltage to the intermediate level voltage for the predetermined time period and then to the low-level voltage.

For example, the first gate signal GW may transition from the low-level voltage to an intermediate voltage level voltage of about −3 V for a 2H period and then to the high-level voltage. The first gate signal GW may transition from the high-level voltage to the intermediate level voltage for the 2H period and then to the low-level voltage. Here, 2H may be twice a scan period H, the low-level voltage may be about −6 V, and the high-level voltage may be about 11 V. Magnitudes of the low-level voltage, the intermediate level voltage, and the high-level voltage are not limited thereto.

The logic unit 35 may output the odd-group gate signal GWA1 based on the first clock signal CLK_O and the plurality of logic input signals GS. The logic unit 35 may output the even-group gate signal GWB1 based on the second clock signal CLK_E and the plurality of logic input signals GS. For the convenience of description, the following description is provided assuming that the first gate signal is the odd-group gate signal GWA1.

A gate signal 901 may be the gate signal generated by the first gate driving circuit in FIG. 5, and a gate signal 903 may be the gate signal generated by the logic unit in FIG. 8.

Referring to FIGS. 7 and 8, the second period P2 may be a compensation period that compensates for the threshold voltage of the first transistor T1. The third period P3 may be a write period in which the data signal is supplied to the pixel. The fourth period P4, in turn, may be a second initialization period that initializes the node to which the pixel electrode of the organic light-emitting diode (OLED) is connected.

During the second period P2, a first gate signal 801 generated by the first gate driving circuit 13-1 (see FIG. 7) may apply a low-level voltage, for example, about −6 V, to the pixel. During the second period P2, a first gate signal 803 generated by the logic unit 35 (see FIG. 8) may apply the low-level voltage to the pixel.

During the third period P3, the first gate signal 801 generated by the first gate driving circuit 13-1 may apply the high-level voltage to the pixel. A difference between the low-level voltage, such as about −6 V, and the high-level voltage, such as about 11 V, may be denoted by A, such as about 17 V.

During the third period P3, the first gate signal 803 generated by the logic unit 35 may apply the intermediate level voltage, such as about −3 V, and the high-level voltage, such as about 11 V, to the pixel. The first gate signal 803 generated by the logic unit 35 may apply the intermediate level voltage, such as about −3 V, to the pixel during a 3-1 period P31. The first gate signal 803 generated by the logic unit 35 may apply the high-level voltage, such as about 11 V, to the pixel during a 3-2 period P32. The first gate signal 803 generated by the logic unit 35 may apply the intermediate level voltage, such as about −3 V, to the pixel during a 3-3 period P33. A difference between the low-level voltage, such as about −6 V, and the intermediate level voltage, such as about −3 V, may be denoted by B, such as about 3 V. A difference between the intermediate level voltage, such as about −3 V, and the high-level voltage, such as about 11 V, may be denoted by C, such as about 14 V.

A kickback variance in the first gate signal 801 generated by the first gate driving circuit 13-1 during the third period P3 may be greater than a kickback variance in the first gate signal 803 generated by the logic unit 35 during the third period P3. The first gate signal 803 generated by the logic unit 35 may reach the high-level voltage, such as about 11 V, through the intermediate level voltage, such as about −3 V, and the kickback variance may thus be smaller than that in the first gate signal 801 generated by the first gate control circuit 13-1. Accordingly, the first gate signal 803 generated by the logic unit 35 may be applied to the plurality of pixels to reduce luminance deviations in the pixels.

During the fourth period P4, the first gate signal 801 generated by the first gate driving circuit 13-1 may apply the low-level voltage, such as about −6 V, to the pixel. During the second period P2, the first gate signal 803 generated by the logic unit 35 may apply the low-level voltage, such as about −6 V, to the pixel.

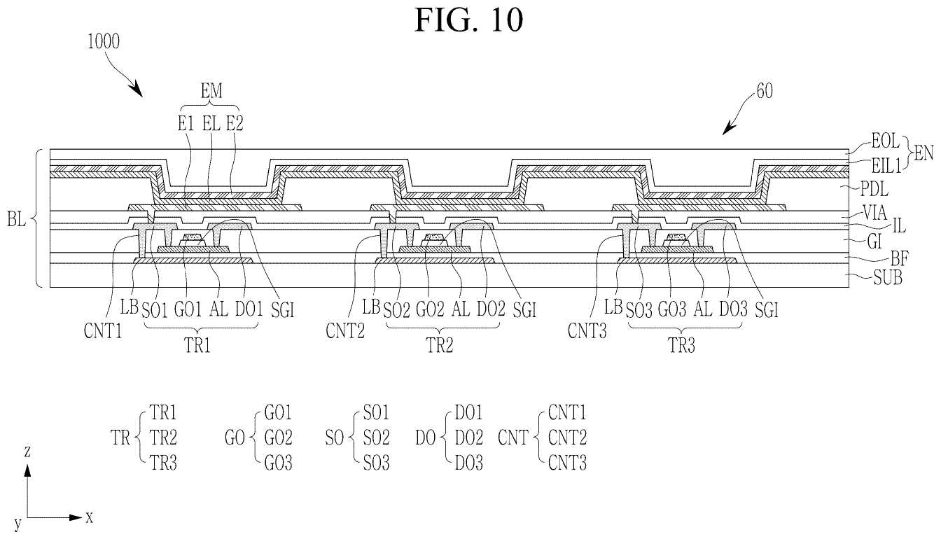

As shown in FIG. 10, a display panel portion including the plurality of pixels connected to the odd-group gate line, according to an embodiment, is indicated generally by the reference numeral 1000.

Referring to FIG. 10, a display panel 60 may include a base layer BL. The base layer BL may include a sub-substrate SUB. The sub-substrate SUB may include a material having a relatively rigid property such as glass or a material having a relatively flexible property such as plastic.

The base layer BL may include a buffer layer BF disposed on the sub-substrate SUB. The buffer layer BF may block impurities from the sub-substrate SUB during formation of a semiconductor layer AL such as to improve properties of the semiconductor layer, and may planarize a surface of the sub-substrate SUB to relieve a stress of the semiconductor layer AL.

A first conductive layer that may include a light-shielding pattern LB may be disposed on the sub-substrate SUB. The first conductive layer may be disposed between the sub-substrate SUB and the buffer layer BF. The light-shielding pattern LB may substantially shield or prevent external light from reaching the semiconductor layer AL of a transistor TR, thereby preventing the properties of the semiconductor layer AL from deteriorating.

The transistor TR may be disposed on the sub-substrate SUB. The transistor TR may be disposed on the buffer layer BF. The semiconductor layer AL of the transistor TR may be disposed on the sub-substrate SUB. The semiconductor layer AL may include any one of amorphous silicon, polycrystalline silicon, and an oxide semiconductor. For the convenience of description, a first transistor TR1, a second transistor TR2, and a third transistor TR3 may be the transistors T2 (see FIG. 6) of the plurality of pixels 2001 to 2003 in FIG. 2, which are connected to the odd-group gate line GWAL1 (see FIG. 2), respectively.

A first gate insulating layer SGI may be disposed on the semiconductor layer AL. A gate conductive layer including a gate electrode GO of the transistor TR may be disposed on the first gate insulating layer SGI.

A second gate insulating layer GI may be disposed on the gate conductive layer. The second gate insulating layer GI may include an inorganic insulating material such as silicon nitride, silicon oxide, or silicon nitride. The second gate insulating layer GI may have a single-layer structure or a multi-layer structure.

An interlayer insulating layer IL may be disposed on the second gate insulating layer GI. The interlayer insulating layer IL may include an inorganic insulating material such as silicon nitride, silicon oxide, and/or silicon nitride. The interlayer insulating layer IL may have a single-layer structure or a multi-layer structure.

A data conductive layer may be disposed on the interlayer insulating layer IL, and may include the first lower electrode SO and second lower electrode DO of the transistor TR. The first lower electrode SO may be a source electrode, and the second lower electrode DO may be a drain electrode. The first lower electrode SO may be connected to the light-shielding pattern LB through a contact CNT.

A planarization layer VIA may be disposed on the data conductive layer

For example, the planarization layer VIA may be disposed on the transistor TR, which includes the semiconductor layer AL, the gate electrode GO, the first lower electrode SO, and the second lower electrode DO. The planarization layer VIA may also be disposed on the second gate insulating layer GI, without limitation thereto.

A light-emitting element EM may be disposed on the planarization layer VIA. The light-emitting element EM may include a pixel electrode E1, a light-emitting layer EL, and a common electrode E2. The light-emitting element EM may be disposed on the planarization layer VIA and electrically connected to the transistor TR.

The pixel electrode E1 may be disposed on the planarization layer VIA, which, in turn, may be disposed on the sub-substrate SUB. The pixel electrode E1 may be an anode of the light-emitting element EM. The pixel electrode E1 may be electrically connected to the transistor TR. The pixel electrode E1 may be connected to the first lower electrode SO of the transistor TR through a contact hole formed in the planarization layer VIA.

A pixel definition layer PDL, which has an opening overlapping the pixel electrode E1, may be disposed on the planarization layer VIA.

The pixel electrode E1 may be disposed in the opening of the pixel defining layer PDL. The opening may correspond to a light-emitting region of the light-emitting element EM.

The light-emitting layer EL is a layer in which electro-optical conversion occurs by coupling electrons to holes, and may include at least one of an organic material and/or an inorganic material that emits light of a predetermined color. The light-emitting layer EL may be disposed in the opening of the pixel definition layer PDL and may overlap with the pixel electrode E1. A part of the light-emitting layer EL may be disposed on the pixel definition layer PDL. The light-emitting layer EL may include an organic light-emitting diode or an inorganic light-emitting diode.

The common electrode E2 may be disposed on the light-emitting layer EL. For example, the common electrode E2 may be a cathode of the light-emitting element EM.

An encapsulation layer EN may be disposed on the common electrode E2. The encapsulation layer EN may encapsulate the light-emitting element EM, including the light-emitting layer EL, to prevent moisture or oxygen from penetrating from the outside. The encapsulation layer EN may include a thin-film encapsulation layer including at least one inorganic layer EIL1 and at least one organic layer EOL.

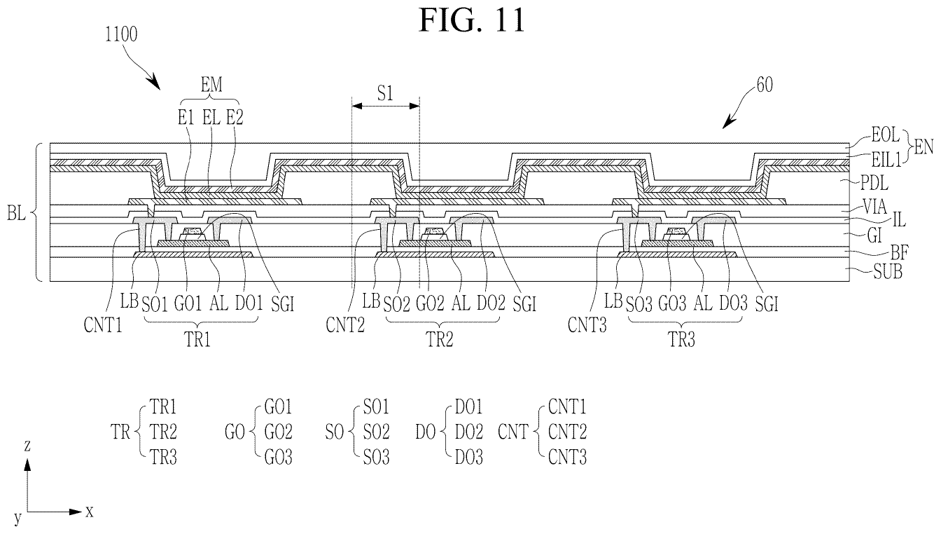

Turning to FIG. 11, a display panel portion including the plurality of pixels connected to the even-group gate line, according to an embodiment, is indicated generally by the reference numeral 1100.

Referring to FIG. 11, the even-group gate line GWBL1 (see FIG. 2) may be connected to the transistor T2 (see FIG. 6) of the plurality of pixels 2004, 2005, and 2006 in FIG. 2. The first transistor TR1, the second transistor TR2, and the third transistor TR3 may be the transistors T2 (see FIG. 6) of the plurality of pixels 2004, 2005, and 2006 in FIG. 2, which are connected to the even-group gate line GWBL1, respectively. The first lower electrode SO may be connected to the light-shielding pattern LB through the contact CNT. A region S1 may include a contact CNT2 connected between a 1-2 lower electrode SO2 and the light-shielding pattern LB.

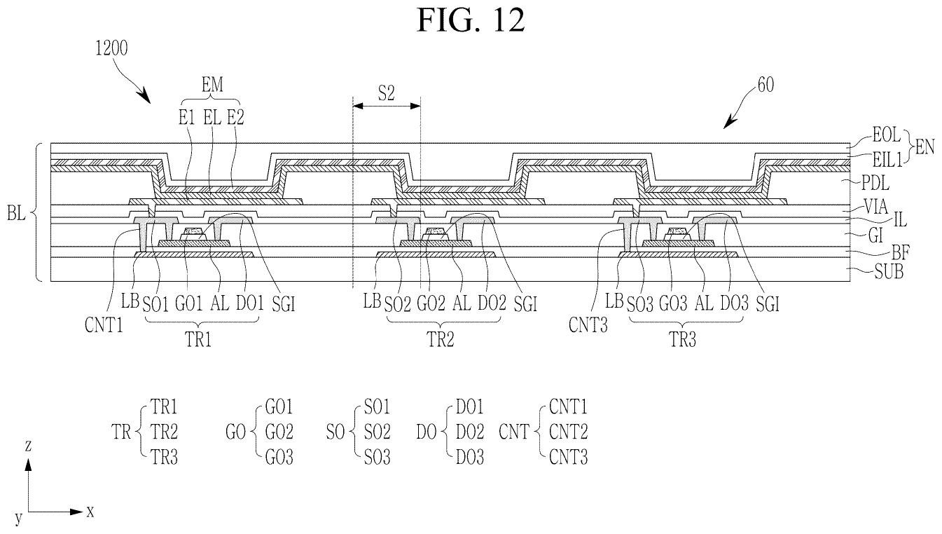

Turning now to FIG. 12, a display panel portion including the plurality of pixels connected to the odd-group gate line, according to a comparative example, is indicated generally by the reference numeral 1200.

Referring to FIG. 12, the odd-group gate line GWAL1 (see FIG. 2) may be connected to the transistor T2 (see FIG. 6) included in each of the plurality of pixels 2001 to 2003 in FIG. 2. The first transistor TR1, the second transistor TR2, and the third transistor TR3 may be the transistors T2 (see FIG. 6) included in the plurality of pixels 2001 to 2003 of FIG. 2, which are connected to the odd-group gate line GWAL1, respectively.

A 1-1 lower electrode SO1 may be connected to the light-shielding pattern LB through a contact CNT1. A 1-3 lower electrode SO3 may be connected to the light-shielding pattern LB through a contact CNT3. However, the 1-2 lower electrode SO2 need not be connected to the light-shielding pattern LB through the contact CNT2. A region S2 need not include the contact CNT2 connected between the 1-2 lower electrode SO2 and the light-shielding pattern LB. Here, the region S2 may have a different height Z while being disposed on the same horizontal planes X and Y as the region S1 in FIG. 11.

Referring to FIG. 3 together, if a total quantity of the contact CNTs is reduced, a path through which the current may flow may be reduced, and a current density may thus be increased, thereby increasing a resistance R of the contact CNT. In addition, a parasitic capacitance C may be reduced if the total quantity of contacts CNTs is reduced. However, an increase in the resistance R may be greater than a reduction in the parasitic capacitance C, and a resistance-capacitance (RC) value may thus be increased if the total quantity of contacts CNTs is reduced. Due to the increased RC value, a delay may occur in the gate signal. For example, the signal delay may occur in the odd-group gate signal 301 (see FIG. 3).

If the odd-group gate signal 301 is delayed, a kickback voltage variance between the gate voltage 305 of the driving transistor included in each of the plurality of pixels 2001 to 2003 and the gate voltage 307 of the driving transistor included in each of the plurality of pixels 2004 to 2006 may be reduced.

When the odd-group gate signal 301 transitions from the high level to the low level, the plurality of pixels 2004 to 2006 may already be charged by the even-group gate signal 303 (see FIG. 3). However, if the odd-group gate signal 301 is delayed, the plurality of pixels 2004 to 2006 may be less affected by the even-group gate signal 303 (see FIG. 3) applied at the high-level voltage.

Accordingly, the charging voltages of the plurality of pixels 2001 to 2003 that receive the odd-group gate signal 301 may be higher than about 0.9 V. The kickback voltage variance, which may be a difference between the charging voltages of the plurality of pixels 2001 to 2003 that receive the odd-group gate signal 301 and the charging voltages of the plurality of pixels 2004 to 2006 that receive the even-group gate signal 303, may be less than 0.5. A luminance deviation occurring between the plurality of pixels 2001 to 2003, to which the odd-group gate signal 301 is applied, and the plurality of pixels 2004 to 2006, to which the even-group gate signal 303 is applied, may be reduced.

Referring back to FIG. 12, the total quantity of contacts CNTs in the plurality of pixels 2001 to 2003 (see FIG. 2) that receive the odd-group gate signal GWA1 and the total quantity of contacts CNTs in the plurality of pixels 2004 to 2006 (see FIG. 2) that receive the even-group gate signal GWB1 may be adjusted.

For example, the quantity of contacts CNTs connected between the first lower electrode SO and the light-shielding pattern LB in the plurality of pixels that receive the odd-group gate signal GWA1 may be reduced to reduce the kickback variance in the odd-group gate signal GWA1 (see FIG. 2), which may be affected more greatly by the kickback variance than the even-group gate signal GWB1. On the contrary, the quantity of contacts CNTs connected between the first lower electrode SO and the light-shielding pattern LB in the plurality of pixels that receive the even-group gate signal GWB1 may be increased to increase the kickback variance in the even-group gate signal GWB1, which may be less affected by the kickback variance than the odd-group gate signal GWA1.

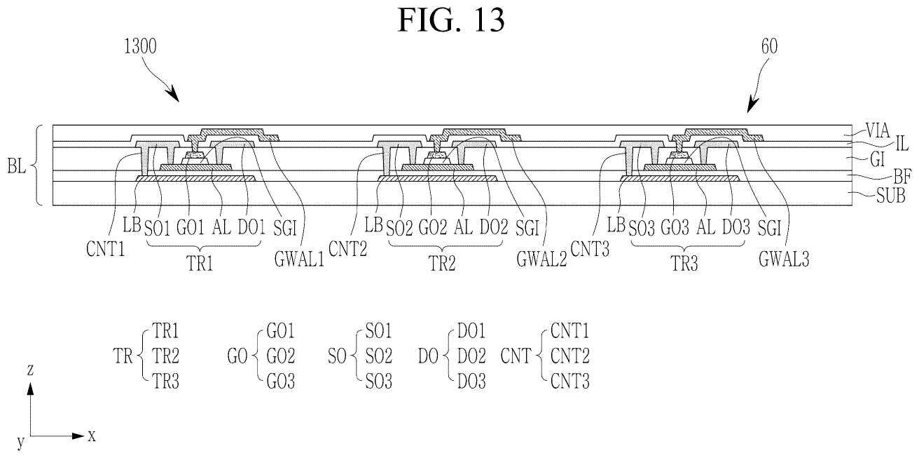

As shown in FIG. 13, a display panel portion including the odd-group gate line to which the odd-group gate signal generated based on the first clock signal is applied, according to an embodiment, is indicated generally by the reference numeral 1300.

Referring to FIG. 13, the display panel 60 may include the base layer BL. The base layer BL may include the sub-substrate SUB. The sub-substrate SUB may include the material having a relatively rigid property such as glass or the material having a relatively flexible property such as plastic.

The base layer BL may include the buffer layer BF disposed on the sub-substrate SUB. The buffer layer BF may block the impurities from the sub-substrate SUB when forming the semiconductor layer AL to thus improve the properties of the semiconductor layer and/or planarize the surface of the sub-substrate SUB, thereby relieving the stress of the semiconductor layer AL.

The first conductive layer, which may include the light-shielding pattern LB, may similarly be disposed on the sub-substrate SUB. The first conductive layer may be disposed between the sub-substrate SUB and the buffer layer BF. The light-shielding pattern LB may prevent external light from reaching the semiconductor layer AL of the transistor TR, thereby preventing the properties of the semiconductor layer AL from deteriorating.

The transistor TR may be disposed on the sub-substrate SUB. The transistor TR may be disposed on the buffer layer BF. The semiconductor layer AL of the transistor TR may be disposed on the sub-substrate SUB. The semiconductor layer AL may include any one or more of amorphous silicon, polycrystalline silicon, and an oxide semiconductor. For the convenience of description, the first transistor TR1, the second transistor TR2, and the third transistor TR3 may be the transistors for sequentially transmitting the odd-group gate signal GWA1 (see FIG. 2) to the odd-group gate lines GWAL1 to GWALP (see FIG. 1), respectively.

The first gate insulating layer SGI may be disposed on the semiconductor layer AL. The gate conductive layer including the gate electrode GO of the transistor TR may be disposed on the first gate insulating layer SGI.

The second gate insulating layer GI may be directly disposed on the gate conductive layer, as well as on portions of the first gate insulating layer SGI, the semiconductor layer AL, and the buffer layer BF. The second gate insulating layer GI may include an inorganic insulating material such as silicon nitride, silicon oxide, or silicon nitride. The second gate insulating layer GI may have the single-layer structure or the multi-layer structure.

The interlayer insulating layer IL may be disposed on the second gate insulating layer GI. The interlayer insulating layer IL may include the inorganic insulating material such as silicon nitride, silicon oxide, or silicon nitride. The interlayer insulating layer IL may have a single-layer structure or a multi-layer structure.

The data conductive layer may be disposed on the interlayer insulating layer IL, and may include the first lower electrode SO and second lower electrode DO of the transistor TR. The first lower electrode SO may be the source electrode, and the second lower electrode DO may be the drain electrode. The first lower electrode SO may be connected to the light-shielding pattern LB through a contact CNT.

The odd-group gate lines GWAL1 to GWALP may be disposed on the data conductive layer. For example, the gate line GWAL1 may be disposed on a 2-1 lower electrode DO1. The gate line GWAL2 may be disposed on a 2-2 lower electrode DO2. The gate line GWAL3 may be disposed on a 2-3 lower electrode DO3.

The planarization layer VIA may be disposed on the odd-group gate lines GWAL1 to GWALP. For example, the planarization layer VIA may be disposed on the transistor TR, which includes the semiconductor layer AL, the gate electrode GO, the first lower electrode SO, and the second lower electrode DO. The planarization layer VIA may also be disposed on the second gate insulating layer GI.

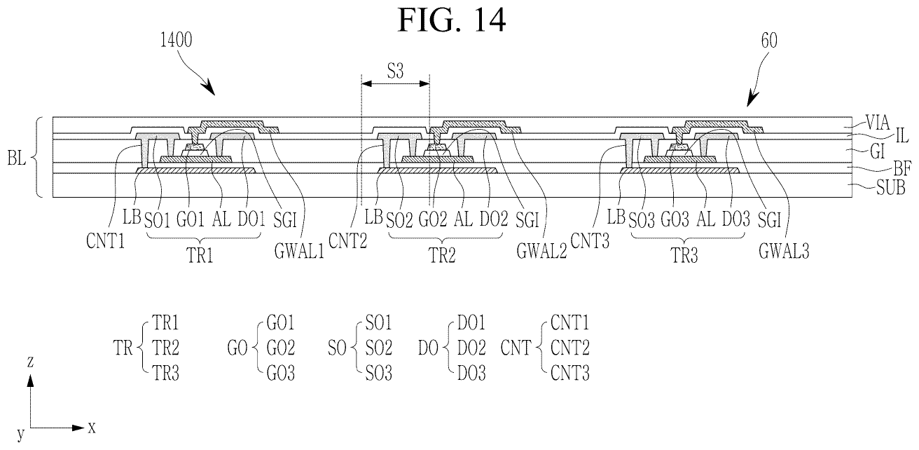

Turning to FIG. 14, a display panel portion including the even-group gate line to which the even-group gate signal generated based on the second clock signal is applied, according to an embodiment, is indicated generally by the reference numeral.

Referring to FIG. 14, the first transistor TR1, the second transistor TR2, and the third transistor TR3 may be the transistors for sequentially transmitting the even-group gate signal GWB1 to the even-group gate lines GWBL1 to GWBLP (see FIG. 1), respectively.

The even-group gate lines GWBL1 to GWBLP may be disposed on the data conductive layer. For example, the gate line GWBL1 may be disposed on the 2-1 lower electrode DO1. The gate line GWBL2 may be disposed on the 2-2 lower electrode DO2. The gate line GWBL3 may be disposed on the 2-3 lower electrode DO3. A region S3 may include the contact CNT2 connected between the 1-2 lower electrode SO2 and the light-shielding pattern LB.

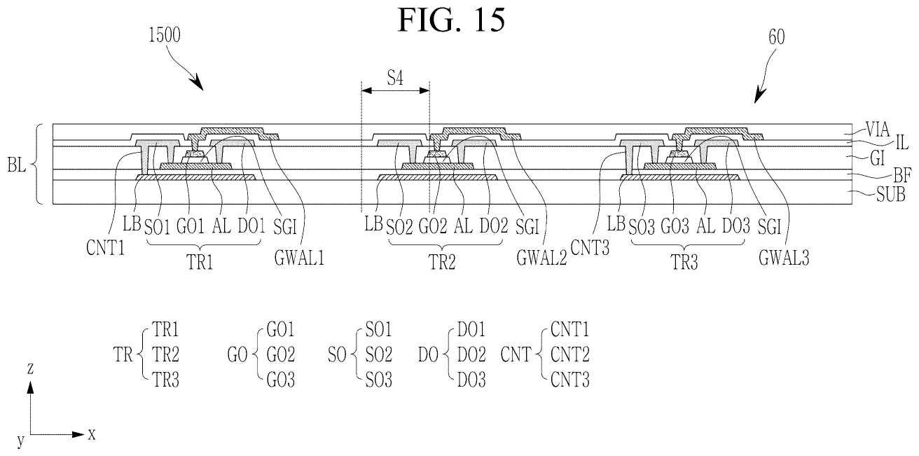

Turning now to FIG. 15, a display panel portion 1500 including the odd-group gate line to which the odd-group gate signal generated based on the first clock signal is applied, according to a comparative example, is indicated generally by the reference numeral 1500.

Referring to FIG. 15, the 1-1 lower electrode SO1 may be connected to the light-shielding pattern LB through the contact CNT1. The 1-3 lower electrode SO3 may be connected to the light-shielding pattern LB through the contact CNT3. However, the 1-2 lower electrode SO2 need not be connected to the light-shielding pattern LB through the contact CNT2. A region S4 need not include the contact CNT2 connected between the 1-2 lower electrode SO2 and the light-shielding pattern LB. Here, the region S4 may have a different height X while being disposed on the same horizontal planes Z and Y as the region S3 in FIG. 14.

If the total quantity of contacts CNTs is reduced, the path through which the current may flow may be reduced. If the path through which the current may flow is reduced, the current density may be increased. If the current density is increased, the resistance R may be increased. The parasitic capacitance C formed from the contact CNTs may be reduced if the total quantity of contacts CNTs is reduced. However, the increase in the resistance R has a greater effect than the reduction in the parasitic capacitance C, and the resistance-capacitance (RC) value may thus be increased if the total quantity of contacts CNTs is reduced. The RC value may be increased to affect voltage rise and voltage fall processes in the circuit, which may cause the signal delay. If the signal delay is increased, a voltage change in the circuit may occur relatively more gradually, which may reduce the kickback phenomenon.

Accordingly, the total quantity of contacts CNTs that receive the first clock signal CLK_O for generating the odd-group gate signal GWA1 and the total quantity of contacts CNTs that receive the second clock signal CLK_E for generating the even-group gate signal GWB1 may be adjusted considering the kickback in the odd-group gate signal GWA1 (see FIG. 2) and the even-group gate signal GWB1 (see FIG. 2).

For example, the total quantity of contacts CNTs connected between the first lower electrode SO and the light-shielding pattern LB receiving the first clock signal CLK_O may be reduced to reduce the kickback in the odd-group gate signal GWA1, which is more affected by the kickback than the even-group gate signal GWB1. On the contrary, the total quantity of contacts CNTs connected between the first lower electrode SO and the light-shielding pattern LB receiving the second clock signal CLK_E may be increased to increase the kickback in the even-group gate signal GWB1, which is less affected by the kickback than the odd-group gate signal GWA1.

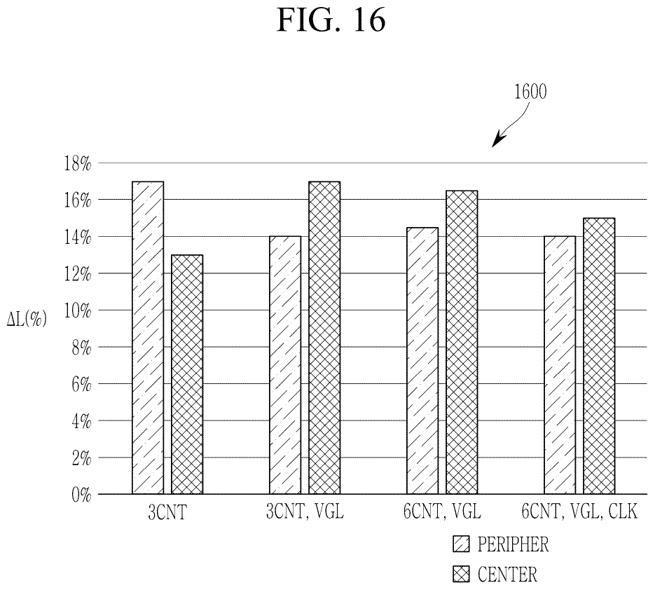

As shown in FIG. 16, a comparison of luminance deviations based on the kickback quantity of odd-group gate lines and even-group gate lines connected to the periphery and center of the display panel, respectively, is indicated generally by the reference numeral 1600.

Referring to FIGS. 1 to 4 and 16, the gate signal may be transmitted to the periphery 61 and the center 62 through the odd-group gate lines GWAL1 to GWALP and the even-group gate lines GWBL1 to GWBLP. luminance deviations may occur between the periphery 61 and the center 62 based on the difference between the kickback quantity of the odd-group gate lines GWAL1 to GWALP and the kickback quantity of the even-group gate lines GWBL1 to GWBLP.

Each of the plurality of first lower electrodes SO (see FIG. 11) included in the plurality of pixels connected to the even-group gate lines GWBL1 to GWBLP in the periphery 61 may be connected to the light-shielding pattern LB (see FIG. 11) through N contacts CNTs (see FIG. 11). Each of the plurality of first lower electrodes SO (see FIG. 12) included in the plurality of pixels connected to the odd-group gate lines GWAL1 to GWALP in the periphery 61 may be connected to the light-shielding pattern LB (see FIG. 12) through N-3 contacts CNTs (see FIG. 12). luminance deviations between the plurality of pixels connected to the odd-group gate lines GWAL1 to GWALP and the plurality of pixels connected to the even-group gate lines GWBL1 to GWBLP, in the periphery 61, may differ by 17%.

Each of the plurality of first lower electrodes SO (see FIG. 11) included in the plurality of pixels connected to the even-group gate lines GWBL1 to GWBLP in the center 62 may be connected to the light-shielding pattern LB (see FIG. 11) through the N contacts CNT (see FIG. 11). Each of the plurality of first lower electrodes SO (see FIG. 12) included in the plurality of pixels connected to the odd-group gate lines GWAL1 to GWALP in the center 62 may be connected to the light-shielding pattern LB (see FIG. 12) through the N-3 contacts CNT (see FIG. 12). luminance deviations between the plurality of pixels connected to the odd-group gate lines GWAL1 to GWALP and the plurality of pixels connected to the even-group gate lines GWBL1 to GWBLP, in the periphery 61, may differ by 13%. Accordingly, a luminance deviation between the periphery 61 and the center 62 may differ by about 4%.

In order to reduce luminance deviations between the periphery 61 and the center 62, the logic unit 35 (see FIG. 8) may set the intermediate level voltage for the first gate signal GW to transition from the low-level voltage to the high-level voltage via the intermediate level voltage, which is the voltage between the low-level voltage and the high-level voltage. The odd-group gate lines GWAL1 to GWALP and the even-group gate lines GWBL1 to GWBLP, which are connected to the periphery 61 and the center 62, respectively, may transmit the odd-group gate signal and the even-group group gate signal to the plurality of pixels by using the intermediate level voltage. Accordingly, luminance deviations between the periphery 61 and the center 62 may differ by about 3%.

To further reduce luminance deviations between the periphery 61 and the center 62, the quantity of contacts in the odd-group gate lines GWAL1 to GWALP in the periphery and the center may be changed. Each of the plurality of first lower electrodes SO (see FIG. 12) included in the plurality of pixels connected to the odd-group gate lines GWAL1 to GWALP in the periphery 61 may be connected to the light-shielding pattern LB (see FIG. 12) through N-6 contacts CNT (see FIG. 12). Each of the plurality of first lower electrodes SO (see FIG. 12) included in the plurality of pixels connected to the odd-group gate lines GWAL1 to GWALP in the center 62 may be connected to the light-shielding pattern LB (see FIG. 12) through the N-6 contacts CNTs (see FIG. 12). Accordingly, luminance deviations between the periphery 61 and the center 62 may differ by about 2%.

In order to further reduce luminance deviations between the periphery 61 and the center 62, the total quantity of contacts CNTs that receive the first clock signal CLK_O for generating the odd-group gate signal may be reduced. On the contrary, the total quantity of contacts CNTs that receive the second clock signal CLK_E for generating the even-group gate signal may be increased. Accordingly, luminance deviations between the periphery 61 and the center 62 may differ by about 1%.

The display device according to an embodiment may be applied to various electronic devices. An electronic device according to an embodiment may include the display device described above, and may further include a module or device having an additional function in addition to the display device.

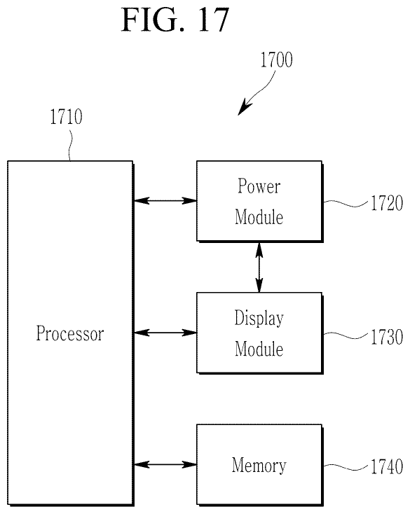

Turning to FIG. 17, an electronic device, according to an embodiment, is indicated generally by the reference numeral 1700. Referring to FIG. 17, an electronic device 1700, according to this embodiment, may include a processor 1710, a power module 1720, a display module 1730, and a memory 1740.

The processor 1710 may include at least one of a central processing unit (CPU), an application processor (AP), a graphic processing unit (GPU), a communication processor (CP), an image signal processor (ISP), and a controller.

The memory 1740 may store data information for an operation of the processor 1710 or the display module 1730. When the processor 1710 executes an application stored in the memory 1740, the image data signal and/or the input control signal may be transmitted to the display module 1730, and the display module 1730 may process the received signal and output image information through a display screen.

The power module 1720 may include a power supply module, such as a power adapter or a battery device, and a power conversion module converting power supplied by the power supply module to thus generate power for an operation of the electronic device 1700. The power module 1720 may provide power to the display module and the processor.

The display module 1730 may include a first pixel connected to the first row and including a first driving transistor, and may generate the first gate signal for applying a third voltage level, which is an intermediate voltage level between a first voltage level for turning on a first driving transistor and a second voltage level for turning off the first driving transistor, to the first driving transistor of the first pixel through the gate line corresponding to the first pixel for the predetermined time period.

The display module 1730 may generate the logic input signal for generating the first gate signal applied to the gate of the first transistor included in the first pixel. The display module 1730 may generate the first gate signal based on the logic input signal, and the first driving transistor may be turned on based on the intermediate level voltage of the first gate signal.

The display module 1730 may include a second pixel connected to the second row adjacent to the first row and including a second driving transistor, and transmit a first data signal to the first pixel and the second pixel, the first pixel and the second pixel being capable of being charged based on the first data signal.

The display module 1730 may transition the first gate signal and the second gate signal from the second voltage level to the third voltage level for the predetermined time period and then to the first voltage level. The display module 1730 may transition the first gate signal and the second gate signal from the first voltage level to the third voltage level for the predetermined time period and then to the second voltage level.

At least one component of the electronic device 1700 described above may be included in the display device according to an embodiment described above. In addition, some individual modules functionally included in one module may be included in the display device, while others may be disposed separately from the display device. For example, the display device may include the display module 1730, and the processor 1710, the memory 1740, and the power module 1720 may be disposed in the form of other devices in the electronic device 1700, rather than the display device.

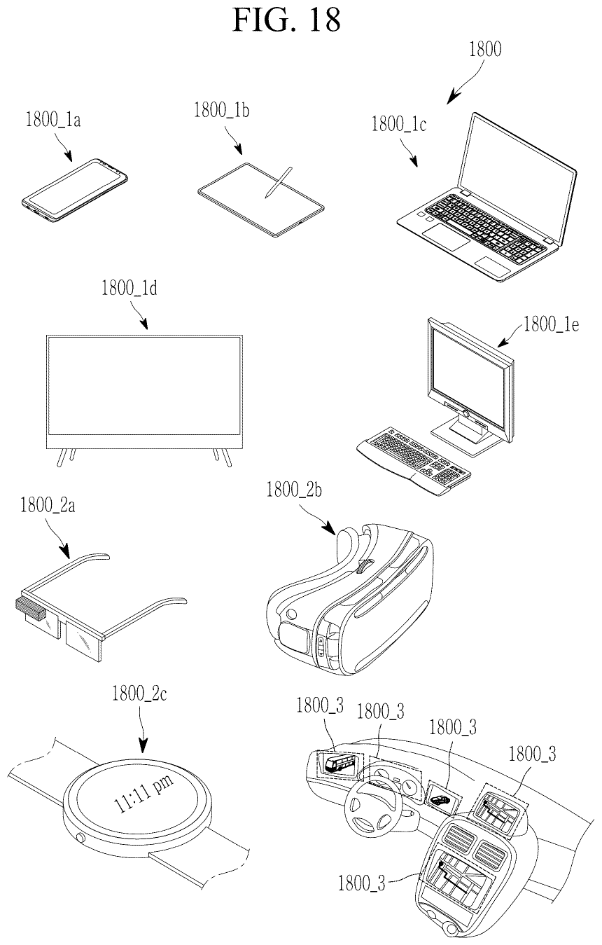

Turning now to FIG. 18, an electronic device, according to a configurable embodiment, is indicated generally by the reference numeral 1800.

Referring to FIG. 18, an electronic device, to which the display device according to an embodiment is applied, may include not only an electronic device for displaying an image, such as a smartphone 1800_1a, a tablet personal computer (PC) 1800_1b, a laptop 1800_1c, a television (TV) 1800_1d, or a desk monitor 1800_1e, but also a wearable electronic device including the display module, such as a smart glasses 1800_2a, a head-mounted display 1800_2b, and a smart watch 1800_2c, and an electronic device 1800_3 for a vehicle that includes a display module, such as a center information display (CID) disposed on the dashboard, center fascia, or dashboard of the vehicle, or a room mirror display.

Although illustrative embodiments have been shown and described, it shall be understood that those of ordinary skill in the pertinent art may make various changes to these and other embodiments without departing from the scope or spirit of the present disclosure as set forth in the following claims.

What is claimed is:

1. A display device comprising:
a display panel having a first row including a first pixel, the first pixel including at least one first switching transistor and a first driving transistor;
a gate driver connected to the display panel through a plurality of gate lines, the gate driver including a logic unit for applying a first gate signal to the first pixel through a gate line corresponding to the first pixel among the plurality of gate lines; and
a data driver connected to the display panel through a data line for applying a first data signal to the first pixel,
wherein the first gate signal applies a third voltage level to the at least one first switching transistor for a predetermined time period,
wherein the third voltage level is an intermediate level voltage between a first voltage level for turning on the at least one first switching transistor and a second voltage level for turning off the at least one first switching transistor.

2. The display device of claim 1, wherein:
the gate driver includes a gate driving circuit that generates a logic input signal for generating the first gate signal applied to a gate of the at least one first switching transistor included in the first pixel.

3. The display device of claim 2, wherein:
the logic unit generates the first gate signal based on the logic input signal, and
the at least one first switching transistor is turned on based on the third voltage level of the first gate signal.

4. The display device of claim 3, wherein:
the display panel includes a second pixel connected to a second row adjacent to the first row and including a second driving transistor,
the logic unit applies a second gate signal to the second pixel through a gate line corresponding to the second pixel, and
the data driver transmits the first data signal to the first pixel and the second pixel through the data line, the first pixel and the second pixel being charged based on the first data signal.

5. The display device of claim 4, wherein:
the first gate signal and the second gate signal transition from the second voltage level to the third voltage level for the predetermined time period and then to the first voltage level.

6. The display device of claim 4, wherein:
the first gate signal and the second gate signal transition from the first voltage level to the third voltage level for the predetermined time period and then to the second voltage level.

7. A display device comprising:
first pixels arranged in a plurality of odd-numbered rows, each first pixel including:
a first light-shielding pattern for shielding external light,
a first gate electrode of a transistor that is disposed on the first light-shielding pattern and connected to one of a plurality of odd-group gate lines,
a first source electrode disposed on the first gate electrode, and
a first contact in electrical contact with the first source electrode and the first light-shielding pattern and providing an electrical connection path between the first source electrode and the first light-shielding pattern; and
second pixels arranged in a plurality of even-numbered rows, each second pixel including:
a second gate electrode of a transistor that is disposed on the first light-shielding pattern and connected to one of a plurality of even-group gate lines,
a second source electrode disposed on the second gate electrode, and
a second contact in electrical contact with the second source electrode and the first light-shielding pattern, providing an electrical connection path between the second source electrode and the first light-shielding pattern, and having a quantity different from that of the first contact.

8. The display device of claim 7, wherein:
a first gate signal including an intermediate level voltage is applied to the first pixels connected to the plurality of odd-numbered rows through the first gate electrode, and
a second gate signal including the intermediate level voltage is transmitted to the second pixels connected to the plurality of even-numbered rows through the second gate electrode.

9. The display device of claim 8, wherein:
the first gate signal and the second gate signal transition from a low-level voltage to the intermediate level voltage for a predetermined time period and then to a high-level voltage.

10. The display device of claim 8, wherein:
the first gate signal and the second gate signal transition from a high-level voltage to the intermediate level voltage for a predetermined time period and then to a low-level voltage.

11. The display device of claim 8, wherein:
the quantity of the first contact is less than that of the second contact.

12. The display device of claim 11, wherein:
the first gate signal transmitted to the one of the plurality of odd-group gate lines is generated based on a first clock signal, and
the second gate signal transmitted to the one of the plurality of even-group gate lines is generated based on a second clock signal different from the first clock signal.

13. The display device of claim 12, further comprising:
a first transistor including:
a second light-shielding pattern for shielding external light,
a third gate electrode to which the first clock signal is applied,
a third source electrode and a third drain electrode, disposed on the third gate electrode,
the one of the plurality of odd-group gate lines disposed on the third drain electrode, and
a third contact in contact with the third source electrode and the second light-shielding pattern and providing an electrical connection path between the third source electrode and the second light-shielding pattern; and
a second transistor including:
a fourth gate electrode to which the second clock signal is applied,
a fourth source electrode and a fourth drain electrode, disposed on the fourth gate electrode,
the one of the plurality of even-group gate lines disposed on the fourth drain electrode, and
a fourth contact in contact with the fourth source electrode and the second light-shielding pattern, providing an electrical connection path between the fourth source electrode and the second light-shielding pattern, and having a quantity different from that of the third contact.

14. The display device of claim 13, wherein:
the quantity of the third contact is less than that of the fourth contact.

15. An electronic device comprising:
a display module having a first row including a first pixel having at least one first switching transistor and a first driving transistor, and generating a first gate signal for applying a third voltage level, which is an intermediate voltage level between a first voltage level for turning on the at least one first switching transistor and a second voltage level for turning off the at least one first switching transistor, to the at least one first switching transistor of the first pixel through a gate line corresponding to the first pixel for a predetermined time period;
a processor for transmitting a data signal input into the display module; and
a power module for supplying power to the display module and the processor.

16. The electronic device of claim 15, wherein:
the display module generates a logic input signal for generating the first gate signal applied to a gate of the at least one first switching transistor included in the first pixel.

17. The electronic device of claim 16, wherein:
the display module generates the first gate signal based on the logic input signal, and
the at least one first switching transistor is turned on based on the third voltage level of the first gate signal.

18. The electronic device of claim 17, wherein:
the display module includes a second pixel connected to a second row adjacent to the first row and including a second driving transistor,
generates a second gate signal to the second pixel through a gate line corresponding to the second pixel, and
transmits a first data signal to the first pixel and the second pixel,
the first pixel and the second pixel being charged based on the first data signal.

19. The electronic device of claim 18, wherein:
the display module transitions the first gate signal and the second gate signal from the second voltage level to a third voltage level for the predetermined time period and then to the first voltage level.

20. The electronic device of claim 18, wherein:
the display module transitions the first gate signal and the second gate signal from the first voltage level to a third voltage level for the predetermined time period and then to the second voltage level.
